(19) United States
(12) Patent Application Publication
(10) Pub. No.: US 2006/0290616 A1
(43) Pub. Date: Dec. 28, 2006

(54) Self-emission panel

(75) Inventors: Ryuji Murayama, Yamagata (JP); Koji Fujita, Yamagata (JP)

Correspondence Address: ARENT FOX PLLC, 1050 CONNECTICUT AVENUE, N.W., SUITE 400, WASHINGTON, DC, 20036, US

(73) Assignee: Tohoku Pioneer Corporation

(21) Appl. No.: 11/471,472

(22) Filed: Jun. 21, 2006

(30) Foreign Application Priority Data
Jun. 22, 2005 (JP) 2005-181467

(51) Int. Cl. G09G 3/30

(52) U.S. Cl. 345/76

(57) ABSTRACT

It is an object of the present invention to provide an improved self-emission panel capable of adjusting its light emission in response to an intensity of an external light without performing some troublesome operations. The panel comprises a plurality of self-emission elements having a light emitting function and a light receiving function, a driving circuit for inputting a driving signal corresponding to an input signal into the self-emission elements so as to effect the light emitting function, a detecting section for detecting an external light intensity by virtue of the light receiving function of the self-emission elements, a control circuit for adjusting a driving signal inputted by the driving circuit into the self-emission elements, based on a detection result of the detecting section.

### BACKGROUND OF THE INVENTION

The present invention relates to a self-emission panel.

The present application claims priority from Japanese Application No. 2005-181467, the disclosure of which is incorporated herein by reference.

There has been known a light emitting/receiving element having light emitting/receiving functions. Further, there has been known a light emitting/receiving apparatus for driving light emitting/receiving elements in a manner such that it is possible to alternatively obtain a light emitting state and a light receiving state (for example, Japanese Unexamined Patent Application Publication No. 2001-203078).

However, with regard to a self-emission panel equipped with self-emission elements such as organic EL (electroluminescence) elements, there is a possibility that the visibility of an image being displayed can decrease due to an inappropriate intensity of an external light. For example, when an emission intensity of self-emission elements is extremely low as compared with an external light, an image being displayed will be dark and thus visibility thereof is low. On the other hand, when an emission intensity of self-emission elements is extremely higher as compared with an external light, an image being displayed will be excessively bright and thus visibility thereof is also low. At this time, a user needs to manually perform a troublesome operation for adjusting an emission intensity (such as brightness level or the like) of self-emission elements.

In order to avoid above problem, light receiving elements such as photodiodes can be provided as additional elements. This, however, will require an additional space for installing the additional light receiving elements and thus makes it difficult to produce an apparatus which is compact in size. Besides, since the aforementioned conventional light emitting/receiving apparatus can only perform an alternative changeover between a light emitting state and a light receiving state, it does not possess the required adjustment function.

### SUMMARY OF THE INVENTION

The present invention is to solve the above problem and makes this as one of its tasks. Namely, it is an object of the present invention to provide an improved self-emission panel capable of adjusting its light emission intensity in response to an intensity of an external light without performing any troublesome operations. Another object of the invention is to provide an improved self-emission panel which is compact in size.

In order to achieve the above objects, the present invention is characterized by at least the following aspects.

According to one aspect of the present invention, there is provided a self-emission panel comprising: a plurality of self-emission elements having a light emitting function and a light receiving function; driving means for inputting a driving signal corresponding to an input signal into the self-emission elements so as to effect the light emitting function; detecting means for detecting an intensity of an external light by virtue of the light receiving function of the self-emission elements; and control means for adjusting the driving signal inputted by the driving means into the self-emission elements 1, based on a detection result of the detecting section.

According to another aspect of the present invention, there is provided another self-emission panel comprising: a plurality of self-emission elements having a light emitting function and a light receiving function, and arranged near intersections of a plurality of data lines with a plurality of scanning lines; driving means for inputting a driving signal corresponding to an input signal into the self-emission elements through the scanning lines and the data lines, thereby effecting the light emitting function; detecting means for detecting an external light intensity by virtue of the light receiving function of the self-emission elements; control means for adjusting the driving signal inputted into the self-emission elements within a predetermined second area, in accordance with a detection result outputted from the detecting means in relation to the self-emission elements within a predetermined first area.

### BRIEF DESCRIPTION OF THE DRAWINGS

These and other objects and advantages of the present invention will become clear from the following description with reference to the accompanying drawings, wherein:

FIG. 1 is a circuit diagram showing an equivalent circuit for explaining a self-emission element of a self-emission panel according to one embodiment of the present invention;

FIGS. 2A and 2B are sectional views showing a self-emission element formed according to one embodiment of the present invention, with FIG. 2A showing an operation of the self-emission element in its luminescent state, and FIG. 2B an operation of the self-emission element in its light receiving state;

FIG. 3 is a graph showing current and voltage characteristics of the self-emission element illustrated in FIGS. 2A and 2B;

FIGS. 4A and 4B are graphs showing detailed examples which explain the current and voltage characteristics of a self-emission element of one embodiment of the present invention (when in its bright and dark states), with FIG. 4A representing a first example showing the current and voltage characteristics of the self-emission element and FIG. 4B representing a second example showing the current and voltage characteristics of the same self-emission element;

FIG. 5 is a functional block diagram of a self-emission panel 100 formed according to one embodiment of the present invention;

FIG. 6 is a circuit diagram showing part and peripheral circuit of a passive driving type self-emission panel adopting the self-emission panel 100 formed according to one embodiment of the present invention;

FIG. 7 is a block diagram showing an operation of the self-emission panel 100 (when light-out) formed according to one embodiment of the present invention;

FIG. 8 is a block diagram showing an operation of the self-emission panel 100 (when being driven) formed according to one embodiment of the present invention;

FIG. 9 is an explanatory view showing displaying timings of the self-emission panel 100;

FIG. 10 is a block diagram showing an operation for detecting a light receiving intensity of self-emission elements having received an inverse bias prior to a displaying timing;

FIG. 11 is a block diagram showing an operation for detecting a light receiving intensity of self-emission elements having received a forward bias during a displaying timing (when scanning);

FIG. 12 is a block diagram showing an operation for detecting a light receiving intensity of self-emission elements having received an inverse bias during a displaying timing (when scanning);

FIG. 13 is a chart showing an operation of a field refreshment driving type self-emission panel adopting the self-emission panel 100 of the present invention;

FIG. 14 is a graph showing an operation in relation to a brightness level control of a control circuit 40 of the self-emission panel 100 formed according to one embodiment of the present invention;

FIGS. 15A, 15B, and 15C are explanatory views showing several different types of self-emission panels 100 formed according to an embodiment of the present invention;

FIG. 16 is a circuit diagram showing part and peripheral circuit of an active driving type self-emission panel adopting the self-emission panel 100 formed according to one embodiment of the present invention; and

FIG. 17 is an explanatory view showing the structure of an organic EL panel, serving as one embodiment of a self-emission panel formed according to one embodiment of the present invention.

### DETAILED DESCRIPTION OF THE PREFERRED EMBODIMENTS

A self-emission panel according to one embodiment of the present invention comprises: a plurality of self-emission elements having light emitting/receiving functions; driving means for inputting a driving signal corresponding to an input signal into self-emission elements so as to effect the light emitting function; detecting means for detecting an intensity of an external light by virtue of the light receiving function of the self-emission elements; and control means for adjusting the driving signal inputted by the driving means into the self-emission elements, in accordance with detection results outputted from the detecting means.

In the self-emission panel having the aforementioned composition, the detecting means operates to detect the intensity of an external light by virtue of the light receiving function of the self-emission elements, while the control means operates to adjust the driving signal inputted by the driving means into the self-emission elements, based on the detection results of the detecting means. In this way, it is possible to adjust the driving signal of the self-emission elements of the self-emission panel so as to adjust the emission intensity (brightness level or the like) in response to the intensity of an external light without performing any troublesome operations. Further, as compared with an apparatus in which light receiving elements for measuring the intensity of an external light are newly installed as additional elements, the self-emission panel of the present invention can provide the following advantages. Namely, since a plurality of self-emission elements have light receiving/emitting functions, and since the control means can adjust the driving signal based on the detection results of the detecting means, it is possible to produce an improved self-emission panel compact in size without installing light receiving elements as additional elements.

In the following, description will be given to explain one embodiment of the present invention with reference to the accompanying drawings.

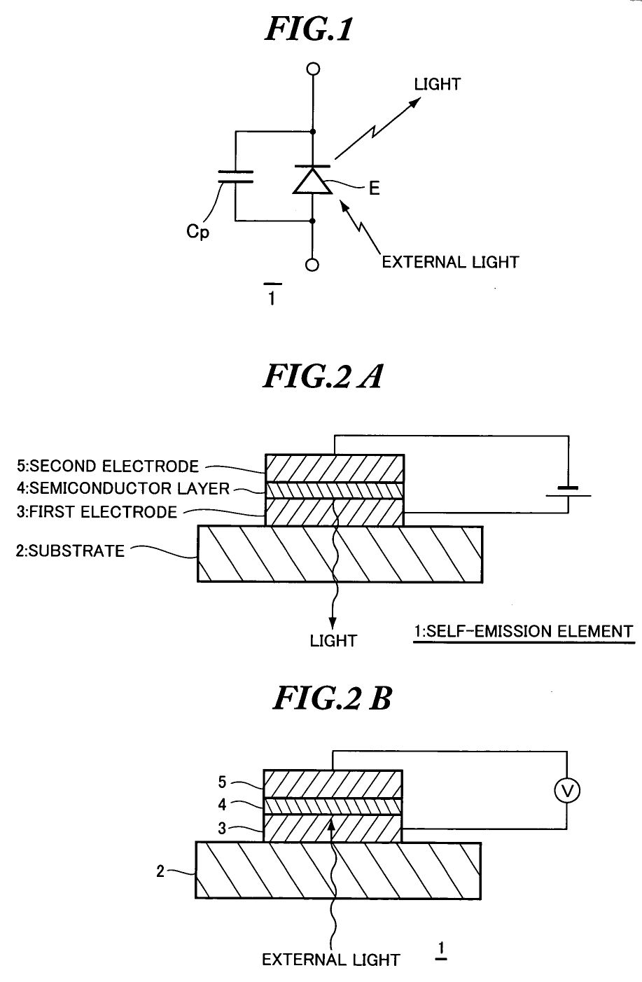

FIG. 1 is an equivalent circuit for explaining a self-emission element 1 of a self-emission panel according to one embodiment of the present invention. Actually, the self-emission element 1 is an organic EL element. As shown in FIG. 1, the equivalent circuit representing a self-emission element includes a diode component E and a parasitic capacitance component Cp which are connected in parallel with each other. In practice, such a self-emission element 1 has both a light emitting function and a light receiving function.

FIGS. 2A and 2B are sectional views showing a self-emission element according to one embodiment of the present invention. FIG. 2A is a view showing an operation of the self-emission element 1 during its light emission. FIG. 2B is a view showing an operation of the self-emission element 1 in its light receiving state. As shown in FIG. 2A, the self-emission element 1 has a substrate 2, a first electrode (hole injection electrode) 3 formed directly or through other layers on the substrate 2, a semiconductor layer 4 formed on the first electrode 3, and a second electrode (electron injection electrode) 5 formed on the semiconductor layer 4.

When the semiconductor layer 4 is formed of a semiconductor having p-n junction, particularly when formed by using a low molecule organic EL element, it will be an organic layer containing a luminescent layer. On the other hand, when the semiconductor layer 4 is formed by using a high molecule organic EL element, it will be an organic layer formed by laminating one or more layers of bipolar material. When light emission is to be effected as shown in FIG. 2A, the first electrode 3 is set as a plus electrode and the second electrode 5 is set as a minus electrode. Then, once an applied voltage is increased, holes and electrons will be recombined at interface so as to emit a light. On the other hand, at the time of light receiving as shown in FIG. 2B, once an external light is applied, an electromotive force can arise between the first electrode 3 and the second electrode 5.

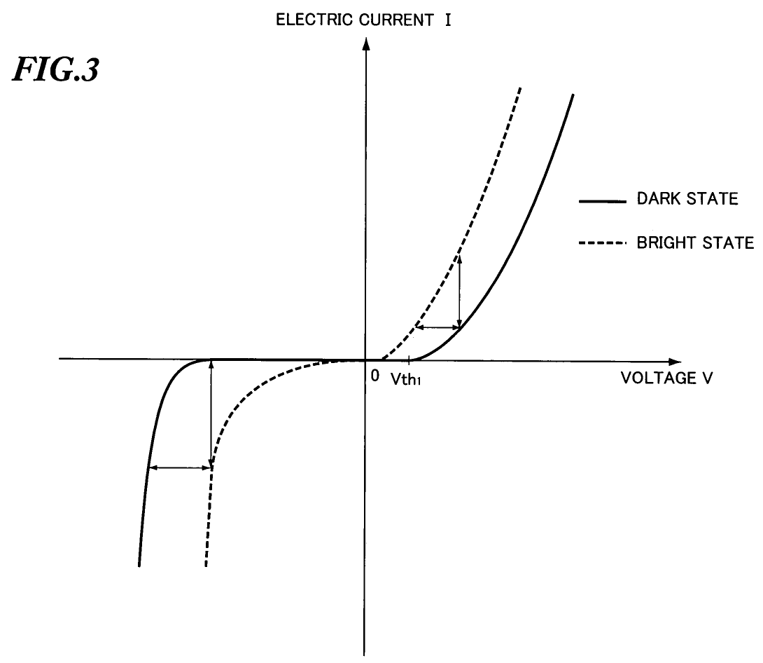

FIG. 3 is a graph showing the current and voltage characteristics of the self-emission element shown in FIG. 2.

As shown in FIG. 3, when a voltage is applied in a forward direction (at the time of forward bias), more specifically, when the first electrode 3 is set as a plus electrode and the second electrode 5 is set as a minus electrode, once an applied voltage is equal to or larger than a threshold Vth1, an electric current I corresponding to a driving voltage V will flow so as to effect a light emission having a brightness level generally proportional to the current I. The self-emission element 1, when at its dark state, exhibits a current/voltage characteristic represented by a solid line in FIG. 3, but exhibits another current/voltage characteristic represented by a dashed line when it receives an external light (at the time of bright state). Namely, there will be an increase in an amount of an electric current flowing in the forward direction into the self-emission element 1 in response to a light receiving intensity. As a result, as compared with a dark state, a driving voltage for the flowing of an amount of current at a bright state will drop down. In the present embodiment, based on a light receiving function in response to a change in the driving characteristic when the self-emission element 1 receives an external light, an intensity of an external light received by the self-emission element 1 can be detected so as to adjust a driving signal to be inputted into the self-emission element 1 in response to a detection result. In more detail, it is required to measure an electric current flowing into the self-emission element 1 and a voltage between the two electrodes of the self-emission element 1 so as to detect the intensity of an external light, thereby adjusting the driving signal being inputted into the self-emission element 1 in accordance with the detection result.

On the other hand, when a voltage is applied in an inverse direction (at the time of an inverse bias), more specifically, when the first electrode 3 is set as a minus electrode and the second electrode 5 is set as a plus electrode, there will be a weak current flowing in an inverse direction into the self-emission element 1 due to a diode characteristic, as shown in FIG. 3. As described above, the self-emission element 1, when at its dark state, exhibits a current/voltage characteristic represented by a solid line in FIG. 3, but exhibits another current/voltage characteristic represented by a dashed line when it receives an external light (at the time of a bright state). Namely, the self-emission element 1, when receiving an external light under a condition where a weak current flows (at the time of a bright state), will have an increased inverse current in response to a light receiving intensity. At this time, since an electric current generated when an inverse bias is applied is larger than an electric current generated when a forward bias is applied, it is possible to obtain a relatively large resolution of optical detection. For this reason, as compared with an optical detection ability at the time a forward bias is applied, it is allowed to obtain a relatively high optical detection ability at the time an inverse bias is applied.

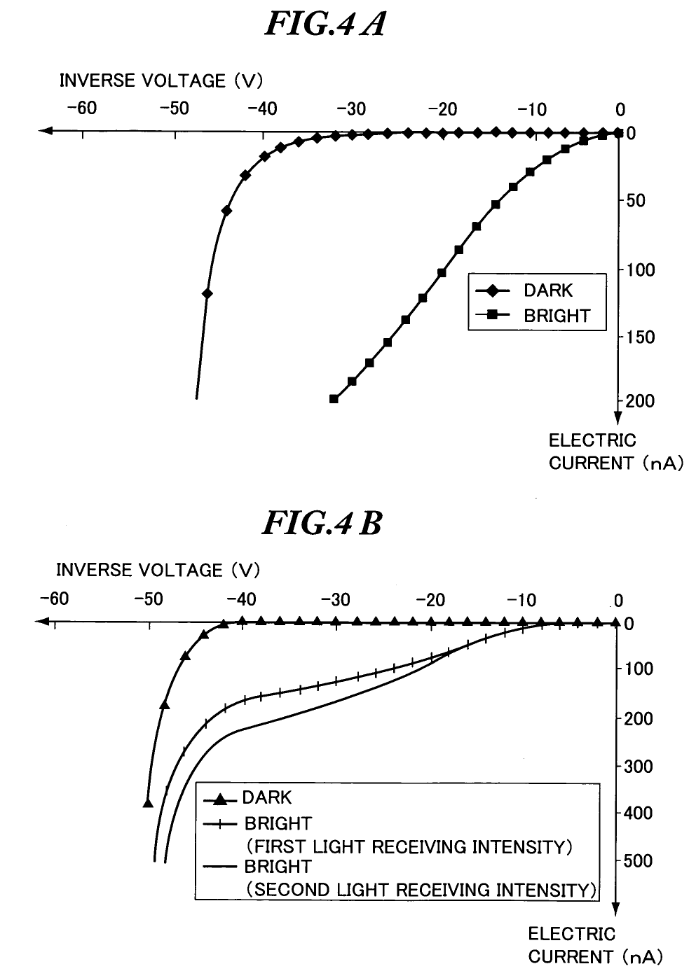

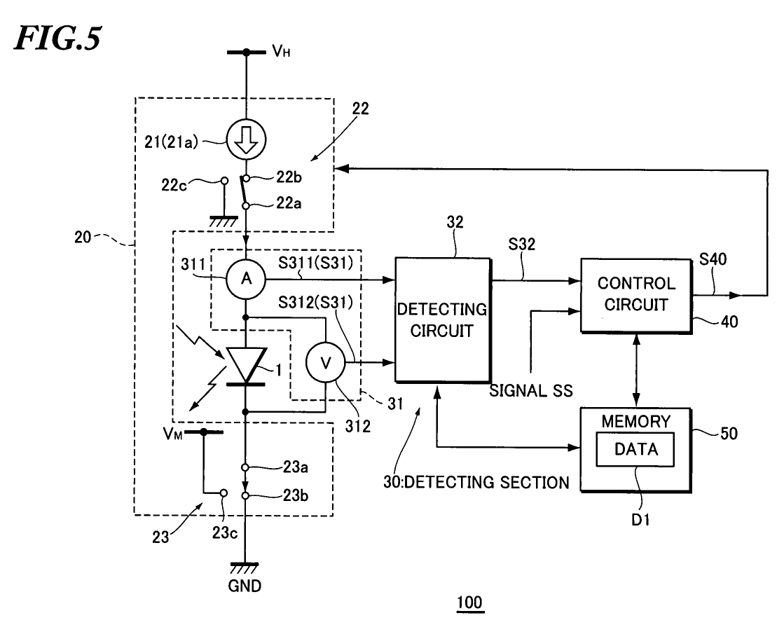

In order to confirm the light emitting/receiving functions of the self-emission element of the present embodiment, the inventors of the present invention have measured the current/voltage characteristics of the self-emission element. FIGS. 4A and 4B are graphs showing a first example and a second example of current/voltage characteristics of a self-emission element formed according to one embodiment of the present invention. Here, in each of the graphs, a horizontal axis represents a voltage (V: volt) and a vertical axis represents an electric current (nA). As can be seen from FIGS. 4A and 4B, a photocurrent and a photo electromotive force can induce a relatively larger current in a bright state than in a dark state. Further, it has also been conformed that a driving voltage for applying a certain current in a bright state is lower than in a dark state.

For example, it is preferable to measure the current/voltage characteristics of the self-emission element 1 in advance, and store data indicating the measurement result, so as to perform a desired detection and a desired control with reference to the foregoing data (when detecting a light receiving intensity). In this way, it is possible to highly accurately detect a light receiving intensity and adjust a driving signal on a self-emission panel 100.

FIG. 5 is a functional block diagram of a self-emission panel formed according to one embodiment of the present invention.

As shown in FIG. 5, the self-emission panel 100 of the present embodiment comprises self-emission elements 1, a driving circuit 20, a detecting section 30, a control circuit 40, and a memory 50. The self-emission elements 1 correspond to an embodiment of the self-emission element of the present invention, and the driving circuit 20 corresponds to an embodiment of the driving means of the present invention. Further, the detecting section 30 corresponds to an embodiment of the detecting means of the present invention, and the control circuit 40 corresponds to an embodiment of the control means of the present invention.

The self-emission elements 1 have the aforementioned light emission/reception functions. The drive circuit 20 inputs a driving signal S20 corresponding to an input signal SS into the self-emission elements 1 so as to effect a light emission function. In more detail, the drive circuit 20 inputs the driving signal S20 into the self-emission elements 1 in accordance with a signal S40 outputted from the control circuit 40 in response to the input signal SS.

As shown in FIG. 5, the driving circuit 20 has a power unit 21, a first switch 22, and a second switch 23. The power unit 21 supplies an electric power which is applied to the self-emission elements 1. The power supply unit 21 is comprised of a constant current source 21a or a constant voltage source. In the present embodiment, one end of the power unit 21 is connected to a power source voltage VH, and the other end thereof is connected to the first switch 22. The first switch 22 has a function of making ON or OFF the power supply to the self-emission elements 1, and another function of cooperating with the second switch 23 to set the direction of a bias which is applied to the self-emission elements 1. For example, as shown in FIG. 5, the first switch 22 has a fixed terminal 22a, a terminal 22b, and a terminal 22c. The fixed terminal 22a is connected to one end (the first electrode 3) of each self-emission element 1 through the detecting section 30, and the fixed terminal 22b is connected to the power unit 21, while the terminal 22c is connected to a reference potential GND. As shown in FIG. 5, the second switch 23 has a fixed terminal 23a, a terminal 23b, and a second terminal 23c. The fixed terminal 23a is connected to the other end (the second electrode 5) of each self-emission element 1, the terminal 23b is connected to the reference potential GND, and the terminal 23c is connected to a power source voltage VM. Here, the power source voltage VM is allowed to be at the same voltage as the power source voltage VH, or at a voltage which is different from the power source voltage VH.

The control circuit 40, at the time of non-driving, outputs into the driving circuit 20 a control signal S40 for connecting the terminal 22a with the terminal 22c and for connecting the terminal 23a with the terminal 23b. In this way, the driving signal will not be inputted into the self-emission elements 1 so that the self-emission elements 1 will be in a light-out state. Further, the control circuit 40, at the time of driving (when a forward bias is applied), inputs into the driving circuit 20 a control signal S40 for connecting the terminal 22a with the terminal 22b and for connecting the terminal 23a with the terminal 23b. In this way, when a forward bias is applied to the self-emission elements 1 and a driving voltage equal to or higher than the threshold is applied, the self-emission elements 1 will emit lights at a brightness level corresponding to an electric current flowing into the self-emission elements 3. Further, the control circuit 40, at the time of driving (when an inverse bias is applied), outputs into the driving circuit 20 a control signal S40 for connecting the terminal 22a with the terminal 22c and for connecting the terminal 23a with the terminal 23b. In this way, an inverse bias is applied to the self-emission elements 1 so that the self-emission elements are in a light-out state (although the driving signal is being applied, the self-emission elements are not lighting and the brightness level is almost zero).

The detecting section 30 detects the intensity of an external light by virtue of the light receiving function of the self-emission elements 1. In more detail, the detecting section 30 detects the intensity of an external light received by the self-emission elements 1, based on the light receiving function corresponding to a change in the driving characteristic of the self-emission element 1 (which change is caused by light reception). The detecting section 30 outputs a signal S32 indicating a detection result into the control circuit 40. More specifically, the detecting section 30, under a condition in which a forward bias or an inverse bias is applied to the self-emission elements 1, will operate to detect the intensity of an external light, in accordance with a change in the value of an electric current flowing into the self-emission elements 1 as well as a change in the voltage applied to the self-emission elements 1 (which changes are all caused due to the light receiving function) As shown in FIG. 5, the detecting section 30 has a measuring circuit 31 and a detecting circuit 32. The measuring circuit 31 measures the value of a current or a voltage applied to the self-emission elements 1, and outputs a signal S31 indicating the measurement result to the detecting circuit 32. Here, the measuring circuit 31 is suitably comprised of a current measuring circuit 311 and a voltage measuring circuit 312. As shown in FIG. 5, the current measuring circuit 311 is provided between the self-emission elements 1 and the driving circuit 20 to measure an electric current flowing into the self-emission elements 1 and to output a signal S311 (S31) indicating the measurement result into the detecting circuit 32. On the other hand, as shown in FIG. 5, the voltage measuring circuit 312 is provided to measure a voltage between the two terminals of each self-emission element 1, and output a signal S312 (S31) indicating the measurement result into the detecting circuit 32.

On the other hand, the control circuit 40 adjusts the driving signal S20 inputted by the driving circuit 20 into the self-emission elements 1, in accordance with a detection result produced by the detecting section 30. For example, the control circuit 40 adjusts the brightness level of the driving signal S20 inputted by the driving circuit 20 into the self-emission elements 1, in accordance with a detection result produced by the detecting section 30. In detail, the control circuit 40 outputs the signal S40 for adjusting the brightness level into the driving circuit 20.

Further, the memory 50 stores a program having the foregoing functions of the present invention, data D1, and various sorts of initial data. The control circuit 40 effects the functions of the present invention by carrying out the program. The data D1, at the time a brightness level is adjusted, is referred to by the control circuit 40 and the detecting section 30, and contains the data indicating the current/voltage characteristics corresponding to light receiving intensities shown in FIG. 3 and FIG. 4, as well as the data indicating a coordinate relationship between an external light intensity and a brightness level (which is for use in control). Further, the control circuit 40 and the detecting section 30 detect a light receiving intensity with a high precision by referring to data D1.

In the following, description will be given to explain one embodiment of a display panel 10 of the self-emission panel 100.

[Passive Driving Type Self-Emission Panel]

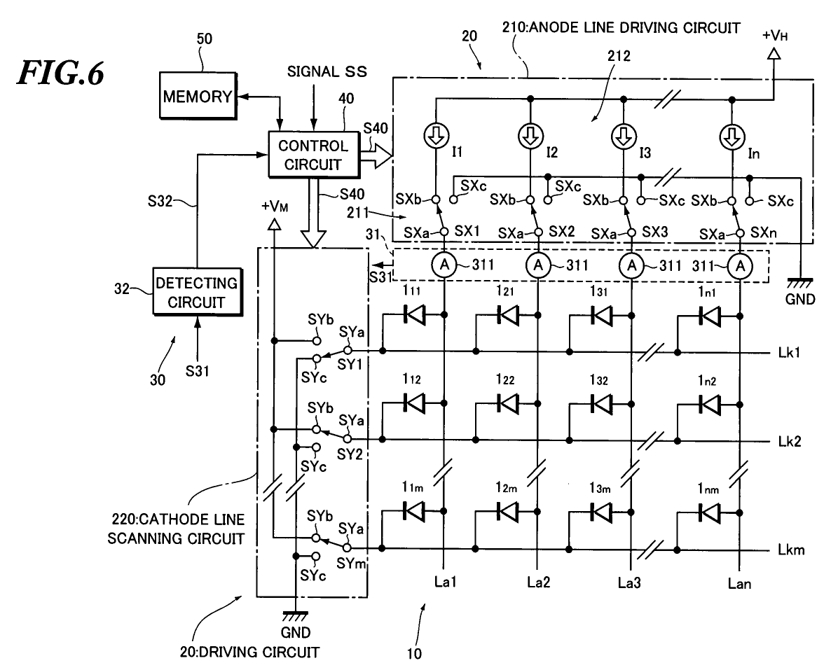

FIG. 6 is a circuit diagram showing a part and peripheral circuits of a passive driving type self-emission panel which has adopted the self-emission panel 100 formed according to one embodiment of the present invention. Although a passive driving type self-emission panel involves two operating manners including cathode-line scanning/anode-line driving, and anode-line scanning/cathode-line driving, the following description is based on a cathode-line scanning/anode-line driving. As shown in FIG. 6, the self-emission panel 100 of the present embodiment comprises a display panel 10, a driving circuit 20, a detecting section 30, a control circuit 40, and a memory 50. Here, description of the elements which are the same as those in other embodiments will be partially omitted. As shown in FIG. 6, the display panel 10 has a plurality of scanning lines (cathode lines) Lₖ₁-Lₖₘ (also called Lₖ), a plurality of data lines (anode lines) Lₐ₁-Lₐₙ (also called Lₐ), and a plurality of self-emission elements 1ₗ₁-1ₙₘ. A plurality of scanning lines Lₖ₁-Lₖₘ are arranged in the longitudinal direction (row direction), and a plurality of data lines Lₐ₁-Lₐₙ are arranged in the vertical direction (column direction). A plurality of self-emission elements 1 are arranged near the intersections of the scanning lines Lₖ₁-Lₖₘ and the data lines Lₐ₁-Lₐₙ, with each self-emission element connected with a scanning line Lₖ and a data line La. More specifically, one end (the first electrode 3) of each self-emission element 1 is connected with a data line Lₐ and the other end (the second electrode 5) thereof is connected with a scanning line Lₖ.

The driving circuit 20 inputs into the self-emission panel 100 the driving signal S40 for driving the self-emission panel 100 in response to a signal (image signal) SS inputted through the control circuit 40. Further, as shown in FIG. 6, the driving circuit 20 has an anode-line driving circuit 210 and a cathode-line scanning circuit 220. The anode-line driving circuit 210 is connected with data lines Lₐ₁-Lₐₙ so as to drive the same, and has a switch group 211 and a power section 212. The switch group 211 corresponds to the first switch 22 shown in FIG. 5, and the power section 212 corresponds to the foregoing power unit 21. Further, the switch group 211 has drive switches sx1-sxn (sx), as shown in FIG. 6. The fixed terminal sxa of each drive switch sx is connected to the data line La, the terminal sxb thereof is connected to the output terminal of the power section 212, and the terminal sxc thereof is connected to the reference potential GND. In practice, each switch sx is formed of a transistor.

The power section 212 of the present embodiment is comprised of constant current sources I₁-Iₙ, with its input terminal connected to the power source voltage VH and its output terminals connected to the terminals sxb of switches sx. The cathode-line scanning circuit 220 is connected to the respective scanning lines Lₖ₁-Lₖₘ and drives the same. Here, the cathode-line scanning circuit 220 has a switch group 221, as shown in FIG. 6. The switch group 221 corresponds to the second switch 23 shown in FIG. 5 and has a plurality of switches SY1-SYm (SY). The fixed terminal SYa of each switch SY is connected to a scanning line Lk, the terminal SYb thereof is connected to the power source voltage VM, and the terminal SYc thereof is connected to the reference potential GND. In practice, each switch SY is formed of a transistor.

The detecting section 30 detects the intensity of an external light received by each self-emission element 1, in accordance with a photocurrent and electromotive force generated on the self-emission element 1 at the time of light receiving. As shown in FIG. 6, the detecting section 30 has a measuring circuit 31 and a detecting circuit 32. In the present embodiment, the measuring circuit 31 comprises current measuring circuits 311 and is provided between the anode-line driving circuit 210 and the display panel 10, with one terminal of each measuring circuit 311 connected to a self-emission element 1 through a data line La and the other connected to the fixed terminal sxa of a switch sx. The current measuring circuits 311 measure currents flowing into the self-emission elements 1 through the data lines La, thereby outputting signals indicating measurement results into the detecting circuit 32. The detecting circuit 32 detects the intensity of an external light received by each self-emission element 1 in accordance with the measurement result produced by the measuring circuit 31. For example, the detecting circuit 32 detects an external light intensity in accordance with a signal S31 outputted from the measuring circuit 31. In addition, the detecting circuit 32 outputs a signal S32 indicating a detection result into the control circuit 40.

The control circuit 40 outputs a control signal to the driving circuit 20 in accordance with a signal SS inputted from the outside. In addition, the control circuit 40 adjusts a driving signal inputted by the driving circuit 20 into each self-emission element 1 in accordance with a detection result outputted from the detecting section 30. For example, the control circuit 40 adjusts a brightness level of a driving signal in accordance with the data D1 or the like stored in the memory 50 or the like.

Next, description will be given to explain an operation of the self-emission panel 100 formed according to one embodiment of the present invention.

[At the Time of Light-Out (Non-Driving)]

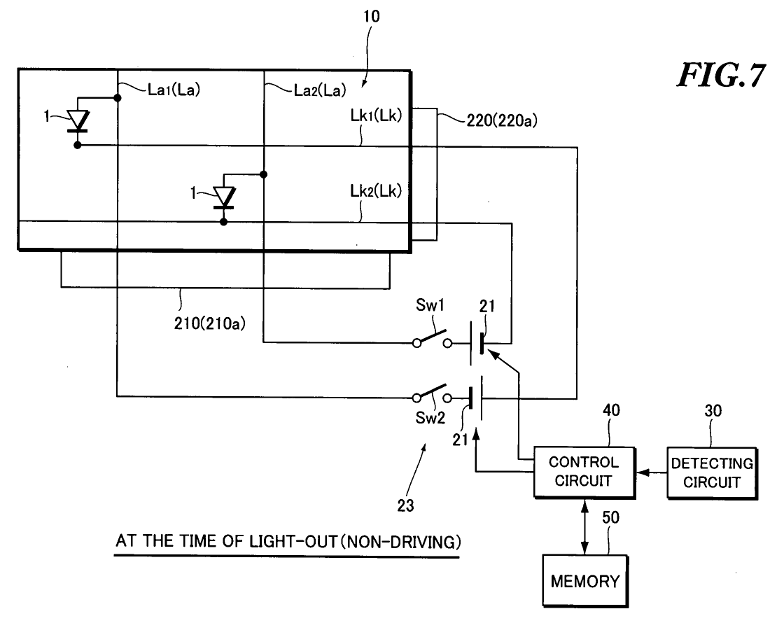

FIG. 7 is a block diagram showing an operation of the self-emission panel 100 (at the time of light-out) according to one embodiment of the present invention. As shown, the control circuit 40, at the time of light-out (non-driving), operates to set a first switch SW1 and a second switch SW2 at a non-connected state, as shown in FIG. 7. In fact, the first switch SW1 and the second switch SW2 shown in FIG. 7 correspond to the first switch 22 and the second switch 23 shown in FIG. 5, thereby forming an arrangement equivalent to a situation in which the control signal S40 shown in FIG. 5 outputs into the driving circuit 20 a control signal S40 for connecting the fixed terminal 22a of the first switch 22 to the terminal 22c and for connecting the fixed terminal 23a of the second switch 23 to the terminal 23c. Here, the first switch SW1 and the second switch SW2 correspond to the switch group 211 and the switch group 221 shown in FIG. 6, thereby forming an arrangement equivalent to a situation in which the control circuit 40 shown in FIG. 6 outputs a control signal S40 for connecting the fixed terminals sxa with the terminals sxc within the entire switch group 221 and for connecting the fixed terminals sya with the terminals syc within the entire switch group 211. In this way, since a driving power is not supplied to the self-emission elements 1, the self-emission elements 1 are in a light-out state.

[At the Time of Driving]

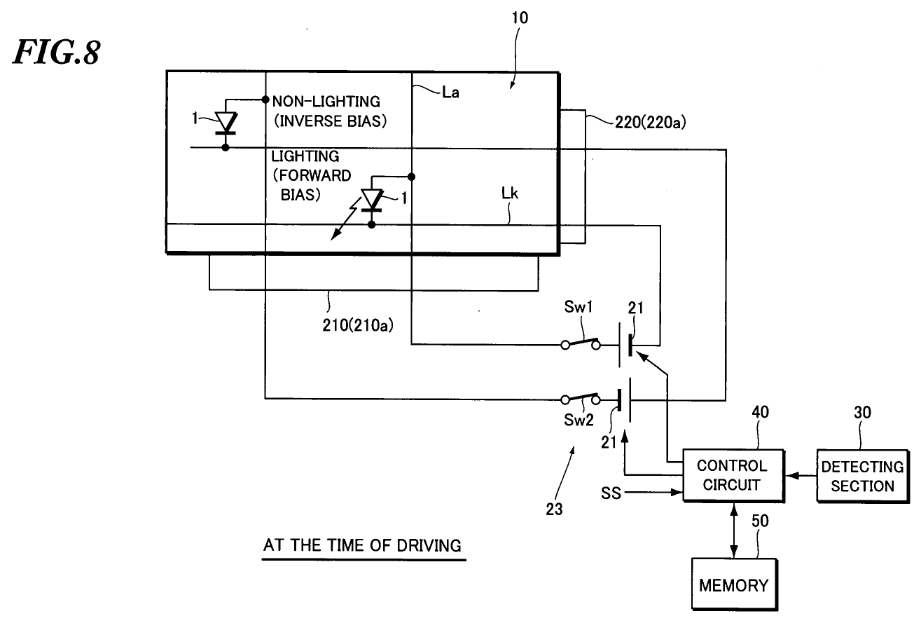

FIG. 8 is a block diagram showing an operation of the self-emission panel 100 (being driven) according to one embodiment of the present invention. As shown, the control circuit 40, at the time of driving, applies a driving signal in response to an input signal SS to the plurality of self-emission elements 1 within the display panel 10 through the driving circuit 20. In detail, as shown in FIG. 8, the control circuit 40 applies a forward bias to each of the self-emission elements corresponding to lighting portions within the display panel 10 and applies an inverse bias to each of the self-emission elements corresponding to light-out portions within the display panel 10, thereby forming an arrangement equivalent to a situation in which the control circuit 40 shown in FIG. 5 outputs into the driving circuit 20 a control signal S40 for connecting the fixed terminal 22a of the first switch 22 to the terminal 22b and for connecting the fixed-terminal 23a of the second switch 23 to the terminal 23b, with respect to the self-emission elements 1 corresponding to lighting portions. Further, with respect to the self-emission elements 1 corresponding to light-out portions, the above arrangement is equivalent to a situation in which the control signal S40 is outputted into the driving circuit 20 for connecting the fixed terminal 22a of the first switch 22 to the terminal 22c and for connecting the fixed-terminal 23a of the second switch 23 to the terminal 23c.

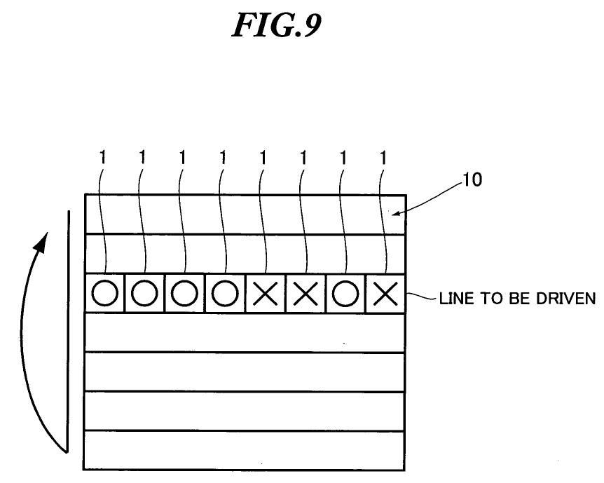

FIG. 9 is an explanatory view showing a display timing of the self-emission panel 100. In fact, the self-emission panel 100 has a plurality of self-emission elements 1 arranged in a matrix array shown in FIG. 6. In this way, an image displaying can be performed while the displaying lines are being sequentially scanned one by one in a manner shown in FIG. 9. For example, in FIG. 9, marks “o” represent self-emission elements 1 corresponding to lighting portions on each scanning line, while marks “X” represent self-emission elements corresponding to light-out portions on each scanning line, thus forming an arrangement equivalent to a situation in which the control circuit 40 shown in FIG. 6 outputs a control signal S40 for connecting the fixed terminal SYa of each switch SY with a terminal SYc (with respect to scanning lines Lk serving as objects to be driven), for connecting the fixed terminal SYa of each switch SY with a terminal SYb (with respect to scanning lines Lk excluding the above scanning lines), for connecting the fixed-terminal sxa of each witch sx with a terminal sxb (with respect to the self-emission elements 1 corresponding to lighting portions), and for connecting the fixed terminal sxa of each witch sx with a terminal sxc (with respect to the self-emission elements 1 corresponding to light-out portions). Subsequently, as shown in FIG. 9, the control circuit 40 sequentially performs a similar operation on the scanning lines Lk. In this way, the self-emission elements 1 having received a forward bias of a value equal to or higher than a threshold will be in a lighting state, while the self-emission elements 1 having received an inverse bias will be in a light-out state.

[Detecting Light Receiving Intensities of Self-Emission Elements 1 each having Received an Inverse Bias Prior to Displaying (Scanning)]

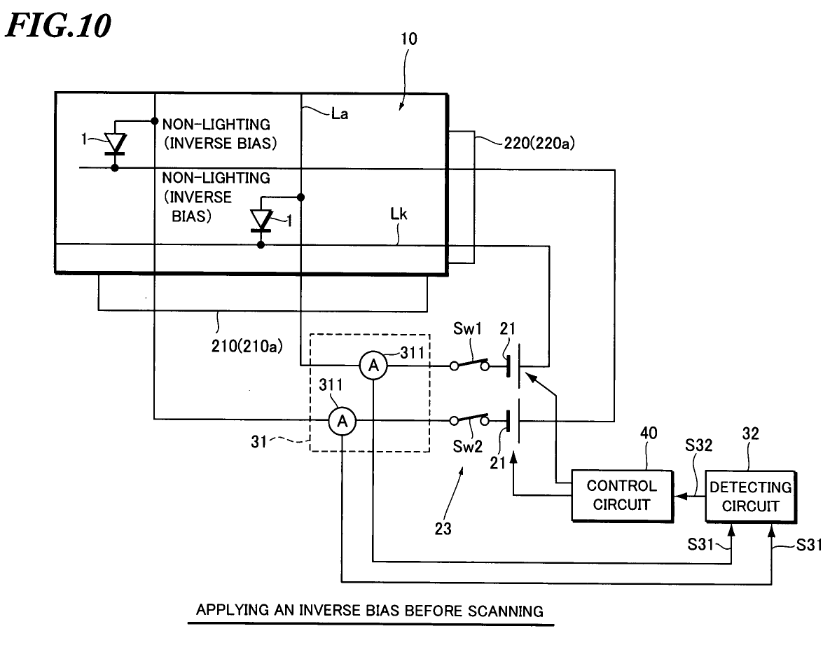

FIG. 10 is a block diagram showing an operation for detecting light receiving intensities of self-emission elements 1 each having received an inverse bias prior to displaying. Where an image displaying is performed while the displaying lines are being sequentially scanned one by one from the top to the bottom in a manner shown in FIG. 9, the control circuit 40 will operate to apply an inverse bias to each self-emission element 1 prior to displaying (scanning) so as to put the respective self-emission elements in a light-out state, thereby forming an arrangement equivalent to a situation in which the control circuit 40 shown in FIG. 5 outputs the control signal S40 into the driving circuit 20 for connecting the fixed terminal 22a of the first switch 22 with the terminal 22c and for connecting the fixed-terminal 23a of the second switch 23 with the terminal 23c. The above arrangement is also an equivalent to a situation in which the control circuit 40 shown in FIG. 6 outputs the control signal S40 for connecting the fixed terminal SYa of each switch SY with a terminal SYb, and for connecting the fixed-terminal sxa of each switch sx with a terminal sxc (corresponding to scanning lines Lk excluding objects to be driven or corresponding to all scanning lines Lk). The detecting section 30, upon detecting the value of an electric current or a voltage applied to the self-emission elements 1 having received an inverse bias, detects a light receiving intensity and outputs a signal S32 indicating the detection result to the control circuit 40. The control circuit 40 adjusts the brightness level of a driving signal S20 through the driving circuit 20 in accordance with a detection result indicated by the signal S40.

As described above, the self-emission panel 100 comprises: a plurality of self-emission elements 1 arranged near the intersections of a plurality of scanning lines Lk with a plurality of data lines La; a driving circuit 20 which inputs a driving signal into the self-emission elements 1 through the scanning lines Lk and the data lines La at the time of driving for scanning; a detecting section 30 for detecting the intensity of an external light before the driving for scanning, in accordance with a driving current or a driving voltage applied in an inverse direction to the self-emission elements 1 through the scanning lines Lk and the data lines La; a control circuit 40 for adjusting the brightness level of the driving signal S20 outputted from the driving circuit 20, in accordance with a detection result outputted from the detecting section 30 at the time of driving for scanning. In this way, since the self-emission panel 100 is not emitting light at this time, it is possible to detect the intensity of an external light with a high precision, thereby making it possible to adjust a brightness level with an increased accuracy in response to an actual detection result.

Moreover, as described above, the detecting section 30, upon detecting a change in the value of an electric current flowing into the self-emission elements 1 at the time of applying a voltage in an inverse direction, can detect a light receiving intensity with a high precision.

[Detecting Light Receiving Intensities of Self-Emission Elements 1 (Lighting Pixels) each having Received a Forward Bias at a Displaying Timing (Scanning)]

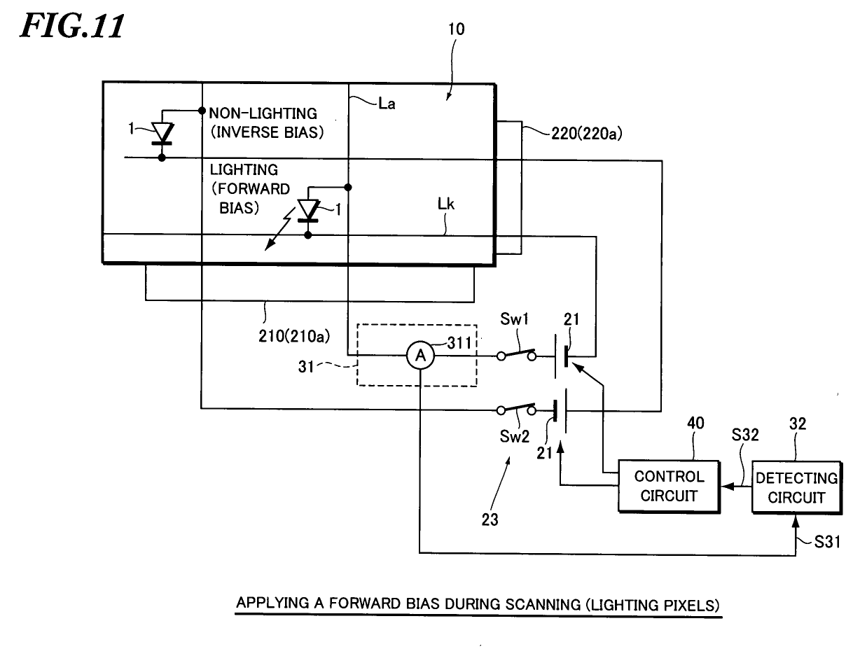

FIG. 11 is a block diagram showing an operation for detecting light receiving intensities of self-emission elements 1 each having received a forward bias at a displaying timing (scanning). In practice, where an image displaying is performed while the displaying lines containing self-emission elements 1 are being sequentially scanned one by one in a manner shown in FIG. 9, the control circuit 40 will operate to apply a forward bias to each self-emission element 1 corresponding to lighting portions of scanning lines Lk to be driven in a manner shown in FIG. 11, thereby forming an arrangement equivalent to a situation in which the control circuit 40 shown in FIG. 5 outputs the control signal S40 into the driving circuit 20 for connecting the fixed terminal 22a of the first switch 22 with the terminal 22b and for connecting the fixed terminal 23a of the second switch 23 with the terminal 23b (with respect to the self-emission elements 1 corresponding to lighting portions). Further, the same arrangement is also an equivalent to a situation in which the control circuit 40, with respect to the self-emission elements 1 corresponding to light-out portions, outputs the control signal S40 into the driving circuit 20 for connecting the fixed terminal 22a of the first switch 22 with the terminal 22c and for connecting the fixed terminal 23a of the second switch 23 with the terminal 23c. This also forms an arrangement equivalent to a situation in which the control circuit 40 shown in FIG. 6 outputs a control signal S40 for connecting the fixed terminal SYa of each switch SY with a terminal SYc (with respect to scanning lines Lk serving as objects to be driven), for connecting the fixed terminal SYa of each switch SY with a terminal SYb (with respect to scanning lines Lk excluding the above scanning lines), for connecting the fixed terminal sxa of each witch sxwith a terminal sxb (with respect to the self-emission elements 1 corresponding to lighting portions on the scanning lines Lk which are to be driven), and for connecting the fixed terminal sxa of each witch sx with a terminal sxc (with respect to the self-emission elements 1 corresponding to light-out portions). The detecting section 30, upon detecting the value of an electric current or a voltage applied to the self-emission elements 1 having received a forward bias, detects a light receiving intensity and outputs the signal S32 indicating the detection result to the control circuit 40. Then, the control circuit 40 adjusts a brightness level through the driving circuit 20 in accordance with a detection result indicated by a signal S40. Afterwards, the control circuit 40 performs similar operations sequentially on the scanning lines Lk.

As described above, the self-emission panel 100 comprises: a plurality of self-emission elements 1 arranged near the intersections of a plurality of scanning lines Lk with a plurality of data lines La; a driving circuit 20 which inputs a driving signal into the self-emission elements 1 through the scanning lines Lk and the data lines La at the time of driving for scanning; a detecting section 30 for detecting the intensity of an external light during the driving for scanning, in accordance with a driving current or a driving voltage applied in a forward direction to the self-emission elements 1; a control circuit 40 for adjusting the brightness level of the driving signal outputted from the driving circuit 20, in accordance with a detection result outputted from the detecting section 30 at the time of driving for scanning. In this way, since the self-emission panel 100 is formed such that its lighting self-emission elements 1 have light receiving functions, the panel 100 can not only perform image displaying but also adjust its brightness level in response to an actual light receiving intensity.

Moreover, as shown in FIG. 3, during light emission of the self-emission elements 1, a forward voltage exceeding an emission threshold voltage Vth1 is applied, so that the self-emission elements 1 emit lights proportional to an electric current in response to a forward voltage (driving voltage). At this time, the detecting section 30 can detect a light receiving intensity with a high precision by detecting a voltage change of the self-emission elements 1 whose driving voltage will decrease when its light receiving intensity is increased.

[Detecting Light Receiving Intensities of Self-Emission Elements 1 (Light-Out Pixels) each Having Received an Inverse Bias at a Displaying Timing (Scanning)]

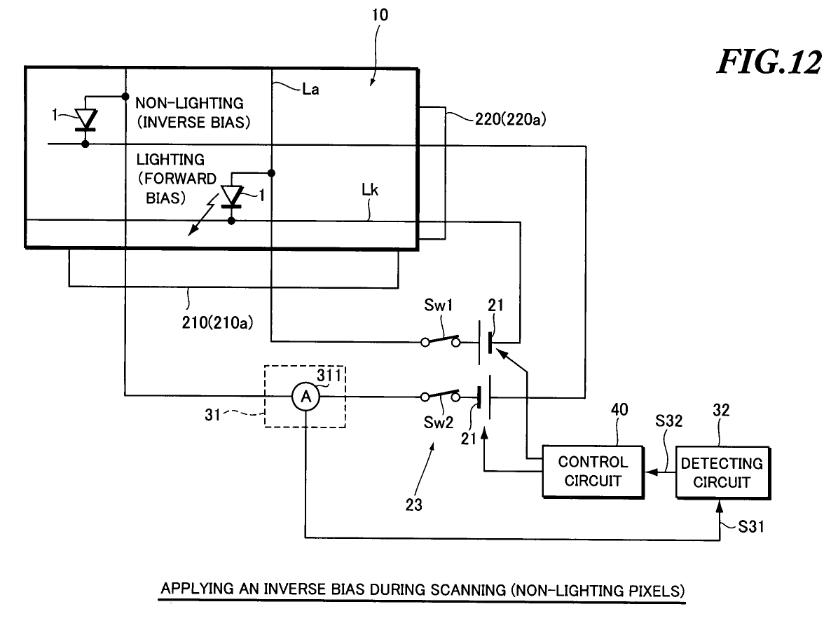

FIG. 12 is a block diagram showing an operation for detecting light receiving intensities of self-emission elements 1 each having received an inverse bias at a displaying timing (scanning).

Where an image displaying is performed while the displaying lines containing self-emission elements 1 are being sequentially scanned one by one in a manner shown in FIG. 9, the control circuit 40 operates to apply an inverse bias to each self-emission element 1 corresponding to light-out portions of scanning lines Lk in a manner shown in FIG. 11, thereby forming an arrangement equivalent to a situation in which the control circuit 40 shown in FIG. 5 outputs a control signal S40 into the driving circuit 20 for connecting the fixed terminal 22a of the first switch 22 with the terminal 22b and for connecting the fixed terminal 23a of the second switch 23 with the terminal 23b (with respect to the self-emission elements 1 corresponding to light-out portions). This also forms an arrangement equivalent to a situation in which the control circuit 40 shown in FIG. 6 outputs a control signal S40 for connecting the fixed terminal SYa of each switch SYwitha terminal SYc (with respect to scanning lines Lk serving as objects to be driven), for connecting the fixed terminal SYa of each switch SY with a terminal SYb (with respect to scanning lines Lk excluding the above scanning lines), and for connecting the fixed terminal sxa of each witch sx with a terminal sxc (with respect to the self-emission elements 1 corresponding to light-out portions). The detecting section 30, upon detecting the value of an electric current or a voltage applied to the self-emission elements 1 having received an inverse bias, detects a light receiving intensity and outputs a signal S32 indicating the detection result to the control circuit 40. Then, the control circuit 40 adjusts a brightness level through the driving circuit 20 in accordance with a detection result indicated by a signal S40.

As described above, the self-emission panel 100 comprises: a plurality of self-emission elements 1 arranged near the intersections of a plurality of scanning lines Lk with a plurality of data lines La; a driving circuit 20 which inputs a driving signal into the self-emission elements 1 through the scanning lines Lk and the data lines La at the time of driving for scanning; a detecting section 30 for detecting the intensity of an external light during the driving for scanning, in accordance with a driving current or a driving voltage applied in an inverse direction to the self-emission elements 1; a control circuit 40 for adjusting the brightness level of the driving signal outputted from the driving circuit 20, in accordance with a detection result outputted from the detecting section 30 at the time of driving for scanning. In this way, since the self-emission panel 100 is formed such that its light-out self-emission elements 1 have light receiving functions, the panel 100 can not only perform image displaying but also adjust its brightness level in response to an actual light receiving intensity. Therefore, since the detecting section 30 detects a light receiving intensity under a condition in which an inverse bias is applied to the self-emission elements 1, it is possible to ensure a higher light receiving sensitivity than a condition in which a forward bias is applied, thereby making it possible to detect a light receiving intensity with a high precision, thus accurately adjusting a brightness level.

[Refreshment Period]

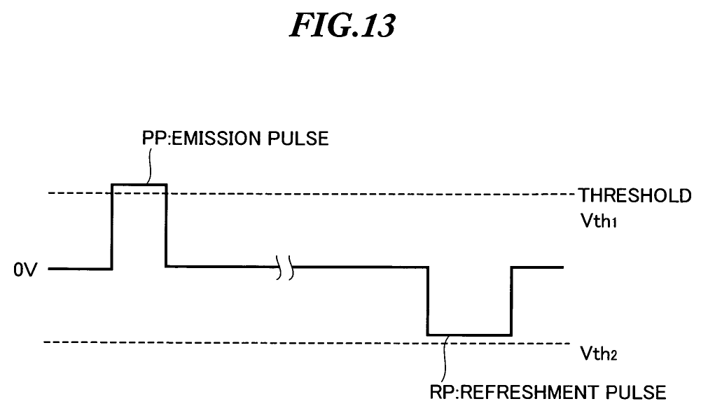

FIG. 13 is an explanatory chart showing an operation of a field refreshment driving type self-emission panel formed by adopting the self-emission panel 100 of the present invention. As shown in FIG. 13, whenever a write-in driving of one-frame (1 field) period is completed, the driving circuit 20 of the present embodiment operates with respect to all the self-emission elements 1 of the display panel 10 to apply a field refreshment pulse RP (refreshment signal) having a voltage close to an emission threshold voltage, at a polarity opposite to a write-in pulse pp having a voltage equal to or higher than an emission threshold voltage Vth1. When the refreshment pulse RP is applied by virtue of the driving circuit 20, the detecting section 30 detects the value of an electric current or a voltage applied to the self-emission elements 1 having received an inverse bias, so as to output a signal S32 indicating a detection result to the control circuit 40. Then, the control circuit 40 adjusts a brightness level through the driving circuit 20 in accordance with a detection result indicated by a signal S40.

As described above, the display panel comprises: a detecting section 30 for detecting an intensity of an external light based on a driving voltage or a driving current at the time of applying a refreshment signal; and a control circuit 40 for adjusting a brightness level of a driving signal outputted from a driving circuit 20, in accordance with a detection result outputted from the detecting section 30 at the time of driving for scanning. In this way, it is possible to perform a light detection under a condition in which an image displaying is not being performed, i.e., the self-emission elements 1 are not emitting lights, thereby making it possible to detect a light receiving intensity with a high precision, thus adjusting the brightness level at a high accuracy.

[An Embodiment of Controlling a Brightness Level using a Control Circuit]

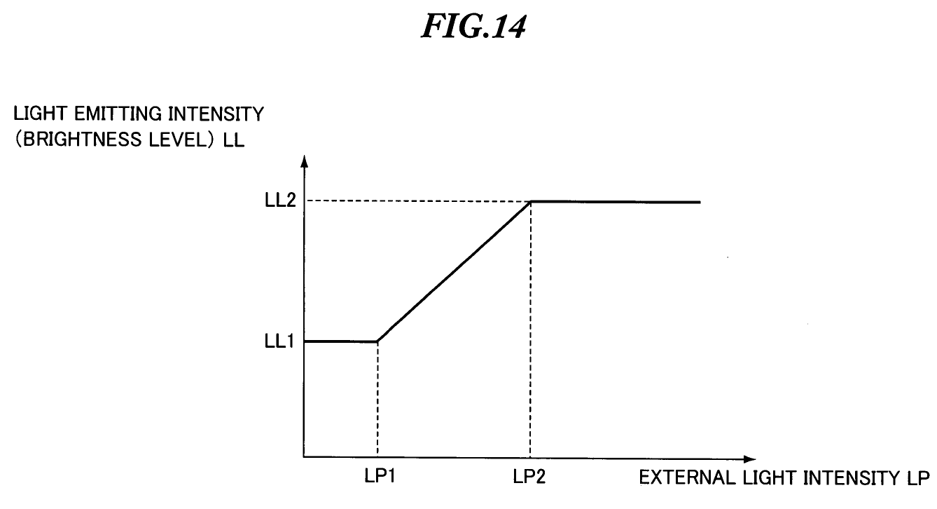

FIG. 14 is an explanatory chart showing an operation for controlling a brightness level by the control circuit 40 of the self-emission panel 100 formed according to one embodiment of the present invention. In FIG. 14, the horizontal axis represents an external light intensity LP and the vertical axis represents a brightness level (an emission intensity) LL. As shown, the control circuit 40 adjusts a brightness level (an emission intensity) of the self-emission elements 1 in response to an intensity LP of an external light received by the self-emission elements 1. In more detail, as shown in FIG. 14, the control circuit 40 performs an adjustment in a manner such that it is possible to ensure a brightness level LL which is substantially proportional to an external light intensity LP. In this way, as described above, since the control circuit 40 is provided to set a brightness level during a dark state detection at a first level and to set a brightness level during a bright state detection at a second level which is higher than the first level, it is possible to set a high brightness level when an external light intensity is relatively high and to set a low brightness level when an external light intensity is relatively low, thereby improving the visibility of the display panel.

Moreover, as shown in FIG. 14, when an external light intensity LPis lower than a first predetermined threshold LP1, it is preferable to set a brightness level LL at its lower limit LL1. For example, when a brightness level LL is adjusted in proportion to an external light intensity LP, a relatively low external light intensity will cause an excessively low brightness level LL, resulting in a low visibility. To avoid this problem, when an external light intensity LP is lower than the first predetermined threshold LP1, the control circuit 40 of the present embodiment operates to set the brightness level LL of the self-emission elements 1 at the lower limit LL1, thereby allowing the self-emission panel 100 to provide an acceptable visibility even if an environment surrounding the panel is relatively dark.

On the other hand, as shown in FIG. 14, when an external light intensity LP is higher than a second predetermined threshold LP1, it is preferable to set a brightness level LL at its upper limit LL2. For example, when a brightness level LL is adjusted in proportion to an external light intensity LP, a relatively high external light intensity will cause an excessively high brightness level LL, resulting in an increase in power consumption and thus a shortened working life. To avoid this problem, when an external light intensity LP is higher than the second predetermined threshold LP2, the control circuit 40 of the present embodiment operates to set the brightness level LL of the self-emission elements 1 at the higher limit LL1, thereby allowing the self-emission panel 100 to reduce its power consumption even if an environment surrounding the panel is relatively bright, thus preventing a shortened working life of self-emission elements 1. Further, since a brightness level can be prevented from increasing excessively, the visibility of the self-emission panel is improved. That is, since the control circuit 40 is provided to set a brightness level at its upper or lower limit, it becomes possible for the display panel to realize a power-saving, a long working life, and an improved visibility.

[Separation of Light Receiving Function from Light Emitting Function]

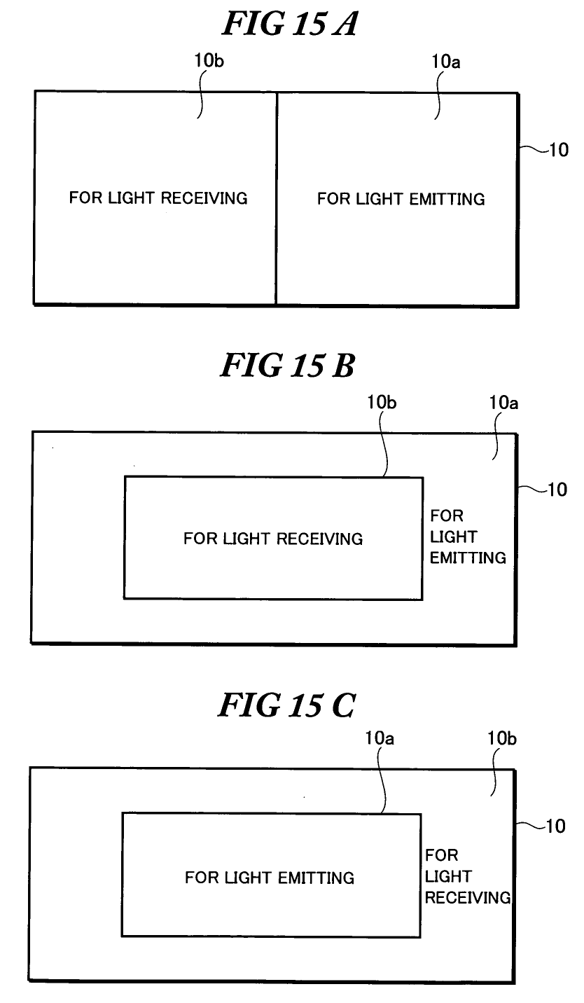

FIGS. 15A to 15C are explanatory views showing several different types of self-emission panels 100 formed according to one embodiment of the present invention. In practice, the control circuit 40 of the present embodiment operates to control a driving signal to be inputted into some self-emission elements 1 within a predetermined second area, in accordance with a detection result fed from the detecting section 30 with respect to the self-emission elements 1 within a predetermined first area. In detail, as shown in FIG. 15A, the whole area of the display panel 10 may be divided into a right area 10a and a left area 10b, with the right area being set as an emission area and the left area as a light receiving area. Further, as shown in FIG. 15B, the whole area of the display panel 10 may be divided into a peripheral area 10a and a central area 10b, with the peripheral area being set as an emission area and the central area as a light receiving area. On the other hand, as shown in FIG. 15C, the whole area of the display panel 10 may be divided in a manner such that its peripheral area 10b is set as a light receiving area and its central area 10a is set as an emission area. Moreover, the above areas may be in the form of circle, rectangle, or lattice.

As described above, the control circuit 40 is provided to control a driving signal to be inputted into the self-emission elements within the predetermined second area, based on a detection result outputted from the detecting section 30 with respect to the self-emission elements in the predetermined first area. In this way, it is possible to adjust an emission intensity of the second area in response to a light receiving intensity of the emission area 10a. Moreover, as compared with an arrangement involving only one or more light receiving elements, since the self-emission panel 100 of the present embodiment can detect a light receiving intensity of a predetermined area (surface area), it is possible to detect an emission intensity with a high precision.

[Active Driving Type Self-Emission Panel]

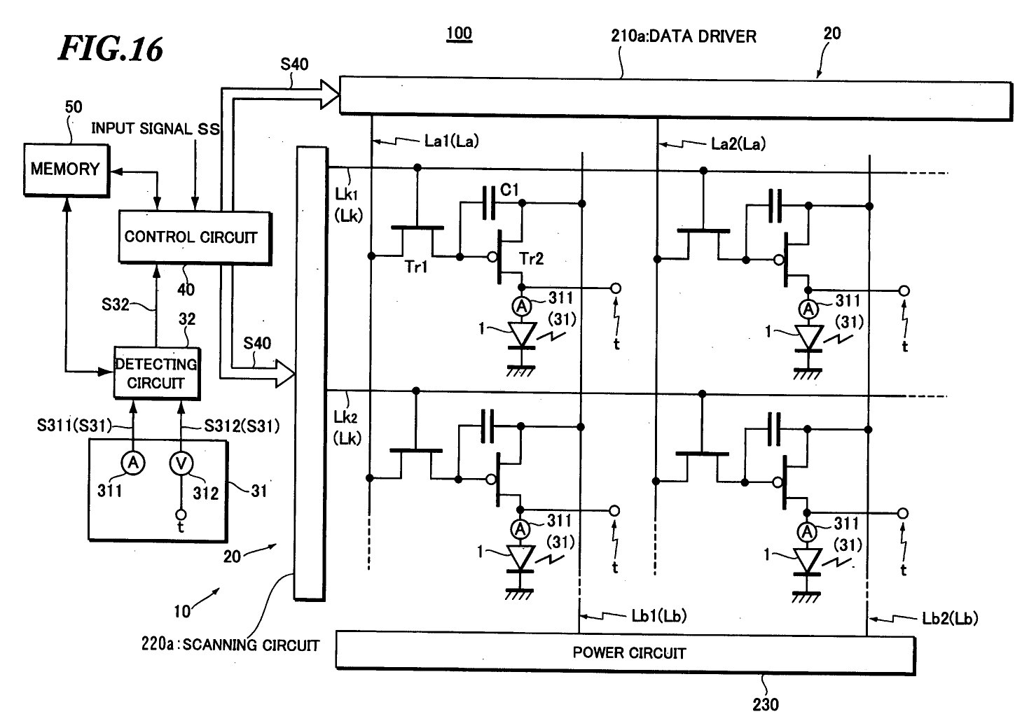

FIG. 16 is a circuit diagram showing a part of an active driving type self-emission panel adopting a self-emission panel 100 formed according to one embodiment of the present invention, also showing a peripheral circuit of the panel. In the following, the self-emission panel of the present invention will be described based on an example in which the panel is used to form an active driving type self-emission panel. As shown in FIG. 16, the self-emission panel 100 includes a display panel 10, a driving circuit 20, a detecting section 30, a control circuit 40, a memory 50, and a power supply circuit 230. However, description of elements common to those in other embodiments will be partially omitted.

Further, as shown in FIG. 16, the driving circuit 20 includes a data driver 210a, a scanning circuit 220a, and a power supply circuit 230. The display panel 10 is equipped with a plurality of self-emission elements 1 which have a light emitting function and a light receiving function. In detail, the display panel 10 has a plurality of scanning lines Lₖ₁-Lₖₘ (it is also called Lk), a plurality of data lines Lₐ₁-Lₐₙ (it is also called La), a plurality of power supply lines L_{b1}-L_{bn} (it is also called Lb), a plurality of self-emission elements Lₗ₁-Lₙₘ, a plurality of control transistors Tr1, a plurality of driving transistors Tr2, and a plurality of charge maintaining capacitors C1. However, FIG. 16 shows only four cells, with other cells being omitted from the diagram.

For example, as shown in FIG. 16, a plurality of scanning lines Lₖ₁-Lₖₘ are arranged in the horizontal direction (row direction) a plurality of data lines Lₐ₁-Lₐₙ are arranged in the longitudinal direction (column direction). The plurality of self-emission elements 1 are arranged near the intersections of the scanning lines with the data lines. The power supply lines Lb are arranged in the column direction on the display panel 10 corresponding to the respective data lines La.

The scanning lines Lk are connected to the scanning circuit 220a, the data lines La are connected to the data driver 210a, and the power supply lines Lb are connected to the power supply circuit 230. Here, each pixel is driven in conductance control manner. In detail, the gates of the control transistors Tr1 each formed by an N-channel type TFT (Thin Film Transistor) are connected to the scanning lines Lk, the sources thereof are connected to the data lines La, and the drains thereof are connected to the gates of the driving transistors Tr2 each formed by a P-channel type TFT (Thin Film Transistor) as well as to the first electrodes of charge maintaining capacitors C1. The second electrodes of the charge maintaining capacitors C1 are connected to the sources of the driving transistors as well as to the power supply lines Lb. The drains of the driving transistors Tr2 are connected to the first electrodes 3 of the self-emission elements 1, while the second electrodes 5 of the self-emission elements 1 are connected to the reference potential GND. In this way, the self-emission elements 1 are arranged near the intersections of the data lines La with the scanning lines Lk in an array of matrix, as shown in FIG. 16.

Moreover, as shown in FIG. 16, the measuring circuit 31 of the detecting section 30 of the present embodiment includes a current measuring circuit 311 and a voltage measuring circuit 312. The current measuring circuit 311 measures an electric current flowing into the self-emission elements 1 and is provided between the driving transistors Tr2 and the self-emission elements 1, as shown in FIG. 16. The voltage measuring circuit 312 measures a voltage between the two electrodes of each self-emission element 1. As shown in FIG. 16, the voltage measuring circuit 312 measures potential differences among the driving transistors Tr2, the nodes t of the self-emission elements 1, and the reference potential GND in each cell.

Next, description will be given to explain an operation of the self-emission panel 100 having the above-described structure. For example, when a forward bias is applied to the self-emission elements 1, ON-voltage will be supplied from the scanning circuit 220a to the gates of the control transistors Tr1 of desired cells (pixels) through the scanning lines Lk, while the control transistors Tr1 cause electric currents (being supplied to the sources thereof) corresponding to a data voltage from the data lines La to flow from the sources to the drains thereof. When the gates of the control transistors Tr are in ON-voltage, the capacitors C1 will be charged with a voltage corresponding to the data voltage, which is then supplied to the gates of the driving transistors Tr2. Then, the driving transistors Tr2 cause an electric current based on the gate voltage and the source voltage to flow into the self-emission elements 1 so as to cause the self-emission elements 1 to emit lights. On the other hand, once the gates of the control transistors Tr1 are in OFF-voltage, the control transistors Tr1 will be cut-off, the drains of the control transistors Tr1 will be open, and the driving transistors Tr2 will be maintained at gate voltage by virtue of charges accumulated in the capacitors C1. Accordingly, the driving current of the driving transistors is maintained so that the light emission states of the self-emission elements 1 are maintained. At this time, the detecting section 30 detects a light receiving intensity, based on a driving current or a driving voltage at the time a forward bias is applied to the self-emission elements 1, while the control circuit 40 adjusts the brightness level of a driving signal outputted from the driving circuit 20, based on a detection result of the detecting section 30.

As described above, even when the self-emission panel 100 is used as an active driving type self-emission panel 100, it is still possible to adjust a brightness level in response to a light receiving intensity of an external light incident on the self-emission elements 1.

However, the present invention should not be limited to the above-described embodiments. Actually, the above-described embodiments can be combined together.

Namely, each self-emission element of the present invention should not be limited to the embodiment shown in FIG. 2. For example, a self-emission element 1 may be fabricated in a manner such that an electron injection electrode is formed on the lower electrode and a hole injection electrode is formed on the upper electrode. Alternatively, a self-emission element 1 may be fabricated in a manner such that a reflection electrode is formed on the lower electrode and an electrode having a transparency is formed on the upper electrode. In addition, it is also possible for each of the low electrode and the upper electrode to have a transparent electrode formed thereon.

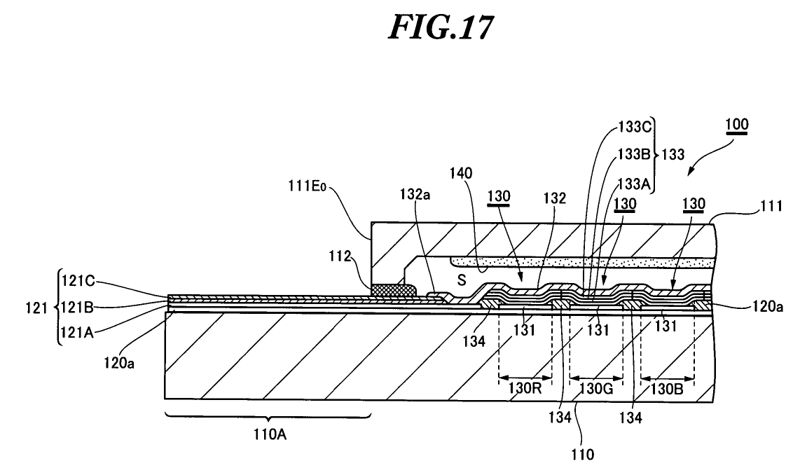

In the following, with reference to FIG. 17, description will be given to explain an organic EL panel serving as an example of the foregoing self-emission electro-optical panel.

As shown, an organic EL panel 100 is formed by interposing an organic layer 133 containing an organic luminescent layer between first electrodes (lower electrodes) 131 on one hand and second electrodes (upper electrodes) 132 on the other, thereby forming a plurality of organic EL elements 130 on the support substrate 110. In an example shown in FIG. 17, a silicone coating layer 120a is formed on the support substrate 110, and a plurality of first electrodes 131 consisting of transparent electrode material such as ITO and serving as anodes are formed on the silicon coating layer 120a. Further, second electrodes 132 consisting of a metal such as A1 and serving as cathodes are formed over the first electrodes 131, thereby forming a bottom emission type panel capable of emitting light from the support substrate 110 side. Moreover, the panel also contains an organic layer 133 including a positive hole transporting layer 133A, a luminescent layer 133B, and an electron transporting layer 133C. Then, the support substrate 110 and a sealing member 111 are bonded together through an adhesive layer 112, thereby forming a sealing area S, thus forming a display section consisting of organic EL elements 130 within the sealing area S.

A display section consisting of organic EL elements 130, as shown in an example of FIG. 17, is so formed that its first electrodes 131 are divided by insulating strips 134, thereby forming a plurality of unit display areas (130R, 130G, 130B) by virtue of the respective organic EL elements 130 located under the divided first electrodes 131. Further, desiccating means 140 is attached to the inner surface of the sealing member 111 forming the sealing area S, thereby preventing a deterioration of the organic EL elements which is possibly caused due to moisture.

Moreover, on the lead-out area 110A formed along the edge of the support substrate 110 there is formed a first electrode layer 121A using the same material and the same step as forming the first electrodes 131, which is separated from the first electrodes 131 by the insulating strips 134. Further, on the lead-out portion of the first electrode layer 121A there is formed a second electrode layer 121B forming a low-resistant wiring portion containing a silver alloy or the like. In addition, if necessary, a protection coating layer 121C consisting of IZO or the like is formed on the second electrode layer 121B. In this way, a lead-out wiring portion 121 can be formed which consists of the first electrode layer 121A, the second electrode layer 121B, and the protection coating 121C. Then, an edge portion 132a of each second electrode 132 is connected to the lead-out wiring portion 121 at edge portion of the sealing area S.

Here, although the lead-out wiring portion of each first electrode 131 is not shown in the drawing, such lead-out wiring portion can be formed by extending each first electrode 131 and leading the same out of the sealing area S. Actually, such lead-out wiring portion can also be formed into an electrode layer forming a low resistant wiring portion containing a silver alloy or the like in a manner similar to an example associated with the above-described second electrode 132.

Then, an edge 111E0 facing the lead-out wiring portion 121 of the sealing member 111 is formed by a hole processing edge formed before bonding together the support substrate 110 and the sealing member 111.

Next, description will be given in more detail to explain the details of the aforementioned organic EL panel 100.

a. Electrodes

Either the first electrodes 131 or the second electrodes 132 are set as cathode side, while the opposite side is set as anode side. The anode side is formed by a material having a higher work function than the cathode side, using a transparent conductive film which may be a metal film such as chromium (Cr), molybdenum (Mo), nickel (Ni), and platinum (Pt), or a metal oxide film such as ITO and IZO. In contrast, the cathode side is formed by a material having a lower work function than the anode side, using a metal having a low work function, which may be an alkali metal (such as Li, Na, K, Rb, and Cs), an alkaline earth metal (such as Be, Mg, Ca, Sr, and Ba), a rare earth metal, a compound or an alloy containing two or more of the above elements, or an amorphous semiconductor such as a doped polyaniline and a doped polyphenylene vinylene, or an oxide such as Cr₂O₃, NiO, and Mn₂O₅. Moreover, when the first electrodes 131 and the second electrodes 132 are all formed by transparent materials, it is allowed to provide a reflection film on one electrode side opposite to the light emission side.

The lead-out wiring portion (the lead-out wiring portion 121 and the lead-out wiring portion of the first electrodes 131, as shown in the figure) are connected with drive circuit parts driving the organic EL panel 100 or connected with a flexible wiring board. However, it is preferable for these lead-out wiring portions to be formed as having a low resistance as possible. Namely, the lead-out wiring portions can be formed by laminating low resistant metal electrode layers which may be Ag-alloy, Cr, Al, or the like. Alternatively, they may be formed by single one electrode of low resistant metal.

b. organic Layer

Although the organic layer 133 comprises one or more layers of organic compound materials including at least one organic luminescent layer, its laminated structure can be in any desired arrangement. Usually, in the case of a low molecule organic EL material, as shown in FIG. 17, there is a laminated structure including, from the anode side towards the cathode side, a hole transporting layer 133A, a luminescent layer 33B, and an electron transporting layer 133C. Each of the hole transporting layer 133A, the luminescent layer 133B, and the electron transporting layer 133C can be in a single-layer or a multi-layered structure. Moreover, it is also possible to dispense with the hole transporting layer 133A and/or the electron transporting layer 133C. On the other hand, if necessary, it is allowed to insert other organic layers including a hole injection layer, and an electron injection layer. Here, the hole transporting layer 133A, the luminescent layer 133B, and the electron transporting layer 133C can be formed by any conventional materials (it is allowed to use either a high molecular material or a low molecular material).

Regarding to a luminescent material for forming the luminescent layer 133B, it is allowed to make use of a luminescence (fluorescence) obtained when the material returns from a singlet excited state to a base state or a luminescence (phosphorescence) obtained when it returns from a triplet excited state to a base state.

c. Sealing Member

In the organic EL panel 100, the covering member for tightly covering organic EL elements 130 may be a plate-like member or container-like member made of metal, glass, or plastic. Here, the sealing member may be a piece of material having a recess portion (a one-step recess or a two-step recess) formed by pressing, etching, or blasting. Alternatively, the sealing member may be formed by using a flat glass plate capable of forming a sealing area S between the flat glass plate and the support substrate 110 by virtue of a spacer made of glass (or plastic). Further, it is also possible to employ an airtight sealing method which uses the above-described sealing member to form a sealing area S, or a solid sealing method in which a filling agent such as a resin or a silicon oil is sealed into the sealing space S, or a film sealing method in which the self-emission elements 130 are sealed up by a barrier film or the like.

d. Adhesive Agent

An adhesive agent forming the adhesive layer 112 may be a thermal-setting type, a chemical-setting type (two-liquid mixture), or a light (ultraviolet) setting type, which can be formed by an acryl resin, an epoxy resin, a polyester, a polyolefine. Particularly, it is preferable to use an ultraviolet-setting epoxy resin adhesive agent which is quick to solidify without a heating treatment.

e. Desiccating Means

Desiccating means 140 may be a physical desiccating agent such as zeolite, silica gel, carbon, and carbon nanotube; a chemical desiccating agent such as alkali metal oxide, metal halide, chlorine dioxide; a desiccating-agent formed by dissolving an organometal complex in a petroleum system solvent such as toluene, xylene, an aliphatic organic solvent and the like; and a desiccating agent formed by dispersing desiccating particles in a transparent binder such as polyethylene, polyisoprene, polyvinyl thinnate.

f. Various Types of Organic EL Panels

The organic EL panel 100 of the present invention can have various types without departing from the scope of the invention. For example, the light emission type of organic EL elements 130 can be bottom emission type which emit light from the substrate 110 side, or top emission type which emit light from the sealing member 111 side (at this time, it is necessary for the sealing member 111 to be made of a transparent material and to dispose the desiccating means 140). Moreover, an organic EL display panel 100 may be a single color display or a multi-color display. In order to form a multi-color display, it is possible to adopt a discriminated painting method or a method in which a single color (white or blue) luminescent layer is combined with a color conversion layer formed by a color filter or a fluorescent material (CF manner, CCM manner), a photobleaching method which realizes a multiple light emission by emitting an electromagnetic wave or the like to the light emission area of a single color luminescent layer, a SOLED (transparent Stacked OLED) method in which two or more colors of unit display areas are laminated to form one unit display area, or a laser transfer method in which low molecular organic material having different luminescent colors are deposited in advance on to different films and then transferred to one substrate by virtue of thermal transfer using a laser. Besides, although the accompanying drawings show only a passive driving manner, it is also possible to adopt an active driving manner by adopting TFT substrate serving as support substrate 110, forming thereon a flattening layer and further forming the first electrodes 131 on the flattening layer.

Moreover, the measuring circuit 31 may suitably include the current measuring circuit 311 and/or the voltage measuring circuit 312. The current measuring circuit 311 is allowed to be a circuit of any type, provided that it can measure an electric current f lowing into the self-emission elements 1, without having to be in the above-described state. Similarly, the voltage measuring circuit 312 is also allowed to be a circuit of any type, provided that it can measure a voltage between the two electrodes of each self-emission element 1, without having to be in the above-described state.

Moreover, the measuring circuit 31 may be provided to handle all of the self-emission elements 1, or only a number of self-emission elements 1 selected in advance, or may be provided for each scanning line, each data line and each power line.

As described above, the self-emission panel according to an embodiment of the present invention comprises: a plurality of self-emission elements 1 having a light emitting function and a light receiving function, a driving circuit 20 which inputs a driving signal corresponding to an input signal into the self-emission elements 1 to effect the light emitting function, a detecting section 30 which detects the intensity of an external light by virtue of the light receiving function of the self-emission elements 1, a control circuit 40 which adjusts the driving signal inputted by the driving circuit 20 into the self-emission elements 1 based on a detection result outputted from the detecting section 30. Therefore, it is possible to provide an improved self-emission panel capable of adjusting the driving signal of the self-emission panel in response to the intensity of an external light without performing a troublesome operation. Moreover, since each of the self-emission elements 1 of the display panel 10 has a light receiving function and a light emitting function, it is allowed to reduce the size of an entire panel device, without installing additional light receiving elements.

Besides, since a detecting section 30 detects the intensity of an external light received by the self-emission elements 1 in accordance with a light receiving function corresponding to a change in the driving characteristic of the self-emission elements 1, it is possible to detect the intensity of an external light with a high precision by virtue of a voltage/current characteristic.

Moreover, since there have been provided the detecting section 30 which detects the intensity of an external light received by the self-emission elements 1, as well as the control circuit 40 which adjusts a driving signal in response to a detection result outputted from the detecting section 30, it is possible to adjust the driving signal while the self-emission elements 1 are being driven, based on a driving current and a driving voltage being inputted into the self-emission elements 1.

Further, the detecting section 30, under a condition in which an inverse bias is applied to the self-emission elements, can detect the intensity of an external light based on the value of an electric current flowing into the self-emission elements 1, thereby ensuring an increased detecting sensitivity. Namely, when an inverse bias is applied to the self-emission elements 1 and such self-emission elements 1 are thus in anon-luminescent state, the detecting section 30 can detect a light receiving intensity, based on a driving current flowing between the positive hole injection electrodes (first electrodes) 3 and the electron injection electrodes (second electrodes) 5, thereby ensuring a high detecting sensitivity.

Moreover, the detecting section 30, under a condition in which a forward bias is applied to the self-emission elements 1, can detect the intensity of an external light based on the value of a driving voltage applied to the self-emission elements 1, thereby detecting a light receiving intensity by virtue of the self-emission elements in their luminescent state. Namely, when a forward bias is applied to the self-emission elements 1 and such self-emission elements 1 are thus in a luminescent state, the detecting section 30 can detect a light receiving intensity, based on a driving voltage applied between the positive hole injection electrodes (first electrodes) 3 and the electron injection electrodes (second electrodes) 5, thereby detecting a light receiving intensity by virtue of the self-emission elements in their luminescent state.

Further, since it is possible to detect a light receiving intensity and to adjust a driving signal in response to a driving state of the self-emission panel 100, it is possible to highly accurately detect a light receiving intensity and adjust a brightness level.

Therefore, it becomes possible to provide an improved self-emission panel having fewer parts and a higher displaying performance.

While there has been described what are at present considered to be preferred embodiments of the present invention, it will be understood that various modifications may be made thereto, and it is intended that the appended claims cover all such modifications as fall within the true spirit and scope of the invention.

What is claimed is:

1. A self-emission panel comprising:
a plurality of self-emission elements having a light emitting function and a light receiving function;
driving means for inputting a driving signal corresponding to an input signal into the self-emission elements so as to effect the light emitting function;
detecting means for detecting an intensity of an external light by virtue of the light receiving function of the self-emission elements; and
control means for adjusting the driving signal inputted by the driving means into the self-emission elements 1, based on a detection result of the detecting section.

2. The self-emission panel according to claim 1, wherein said detecting means detects an intensity of an external light received by the self-emission elements, based on the light receiving function corresponding to a driving characteristic change of the self-emission elements which is caused by a light reception.

3. The self-emission panel according to claim 1, wherein the detecting means, under a condition in which an inverse bias is applied to the self-emission elements, detects the intensity of the external light, based on a value of an electric current generated by the light receiving function and flowing into the self-emission elements.

4. The self-emission panel according to claim 1, wherein the detecting means, under a condition in which a forward bias is applied to the self-emission elements, detects the intensity of the external light, based on a value of a voltage generated by the light receiving function and applied to the self-emission elements.

5. The self-emission panel according to claim 1, including a plurality of self-emission elements arranged near intersections of a plurality of scanning lines with a plurality of data lines,
wherein:
the driving means, during a scanning drive, inputs a driving signal into the self-emission elements through the scanning lines and the data lines;
the detecting means, prior to the scanning drive, detects an intensity of an external light, based on a driving current or a driving voltage applied in an inverse direction to the self-emission elements through the scanning lines and the data lines; and
the control means, during the scanning drive, adjusts a brightness level of a driving signal inputted by the driving means, based on a detection result of the detecting means.

6. The self-emission panel according to claim 1, including a plurality of self-emission elements arranged near intersections of a plurality of scanning lines with a plurality of data lines,
wherein:
the driving means, during a scanning drive, inputs a driving signal into the self-emission elements through the scanning lines and the data lines;
the detecting means, during the scanning drive, detects an intensity of an external light, based on a driving current or a driving voltage applied in a forward direction or an inverse direction to the self-emission elements; and
the control means, during the scanning drive, adjusts a brightness level of a driving signal inputted by the driving means, based on a detection result of the detecting means.

7. The self-emission panel according to claim 1, including a plurality of self-emission elements arranged near intersections of a plurality of scanning lines with a plurality of data lines,
wherein:
the driving means, during a scanning drive, inputs a driving signal into the self-emission elements through the scanning lines and the data lines, and applies a refreshment signal into the self-emission elements in each scanning drive;
the detecting means detects an intensity of an external light, based on a driving current or a driving voltage occurring when the refreshment signal is applied; and
the control means, during the scanning drive, adjusts a brightness level of a driving signal inputted by the driving means, based on a detection result of the detecting means.

8. The self-emission panel according to claim 5, comprising a passive driving type or an active driving type display panel.

9. The self-emission panel according to claim 1, wherein each self-emission element comprises:
a substrate;
a hole injection electrode formed on the substrate;
a semiconductor layer having p-n junction and formed on the hole injection electrode; and
an electron injection electrode formed on the semiconductor layer.

10. The self-emission panel according to claim 1, wherein each self-emission element comprises:
a substrate;
an electron injection electrode formed on the substrate;
a semiconductor layer having p-n junction and formed on the electron injection electrode; and
a hole injection electrode formed on the semiconductor layer.

11. The self-emission panel according to claim 9 or 10, wherein the detecting means, during a light receiving, detects a light receiving intensity, based on a value of an electric current flowing between the hole injection electrode and the electron injection electrode.

12. The self-emission panel according to claim 9 or 10, wherein when a forward bias is applied to the self-emission elements and the self-emission elements emit lights, the detecting means detects the light receiving intensity in accordance with a driving voltage applied between the hole injection electrode and the electron injection electrode.

13. The self-emission panel according to claim 9 or 10, wherein when an inverse bias is applied to the self-emission elements and the self-emission elements are in non-lighting state, the detecting means detects the light receiving intensity in accordance with a driving current flowing between the hole injection electrode and the electron injection electrode.

14. The self-emission panel according to claim 1, wherein the control means sets said brightness level at a first level when a dark state is detected, and sets said brightness level at a second level higher than the first level when a bright state is detected.

15. The self-emission panel according to claim 14, wherein the control means sets a lower limit or an upper limit of said brightness level.

16. A self-emission panel comprising:
a plurality of self-emission elements having a light emitting function and a light receiving function, and arranged near intersections of a plurality of data lines with a plurality of scanning lines;
driving means for inputting a driving signal corresponding to an input signal into the self-emission elements through the scanning lines and the data lines, thereby effecting said light emitting function;
detecting means for detecting an external light intensity by virtue of the light receiving function of the self-emission elements;
control means for adjusting said driving signal inputted into the self-emission elements within a predetermined second area, in accordance with a detection result outputted from the detecting means in relation to the self-emission elements within a predetermined first area.

17. The self-emission panel according to claim 1, wherein said self-emission elements are organic EL elements.
